(19) United States
(12) Patent Application Publication
(10) Pub. No.: US 2023/0249306 A1
(43) Pub. Date: Aug. 10, 2023

(54) METHOD AND APPARATUS FOR PROCESSING SUBSTRATE

(71) Applicant: Tokyo Electron Limited, Tokyo (JP)

(72) Inventors: Yusuke KIKUCHI, Nirasaki City (JP); Masato SHINADA, Tokyo (JP); Motoi YAMAGATA, Tokyo (JP); Hiroshi SONE, Tokyo (JP)

(21) Appl. No.: 18/164,003

(22) Filed: Feb. 3, 2023

(30) Foreign Application Priority Data
Feb. 9, 2022 (JP) 2022-018716

(51) Int. Cl. B23Q 11/10; B23Q 5/34

(52) U.S. Cl. CPC B23Q 11/10; B23Q 5/34; B23Q 2716/00; B23Q 2717/00

(57) ABSTRACT

A method of cooling a substrate by bringing a cooler into direct contact with a stage on which the substrate is placed, and processing the substrate while rotating the stage in a state in which the cooler is moved away from the stage, includes: cooling the cooler to a target temperature in a state in which the stage is brought into direct contact with the cooler, and cooling the stage to an initial cooling temperature; raising a temperature of the stage; controlling the temperature of the stage to a steady cooling temperature when the temperature of the stage reaches the steady cooling temperature; and placing the substrate on the stage kept at the steady cooling temperature, and continuously performing a substrate processing on a plurality of substrates while rotating the stage in a state in which the stage is moved away from the cooler.

### CROSS-REFERENCE TO RELATED APPLICATION

This application is based upon and claims the benefit of priority from Japanese Patent Application No. 2022-018716, filed on Feb. 9, 2022, the entire contents of which are incorporated herein by reference.

### TECHNICAL FIELD

The present disclosure relates to a method and apparatus for processing a substrate.

### BACKGROUND

In an apparatus for processing a substrate such as a semiconductor substrate or the like, for example, a film-forming apparatus, it may be necessary to perform a process at an extremely low temperature. For example, in order to obtain a magnetoresistance element having a high magnetoresistance ratio, a technique is required for forming a magnetic film in an ultra-high-vacuum and extremely-low-temperature environment.

As a technique for uniformly cooling a substrate to an extremely low temperature in an ultra-high vacuum environment, Patent Document 1 discloses a technique that supplies cold heat from a refrigerator to a stage via a refrigerating heat transfer element while supplying a cooling gas to a gap between the rotating stage and the refrigerating heat transfer element. Further, Patent Document 1 discloses that, after preheating the stage to a predetermined temperature, a plurality of substrates are processed continuously.

### Prior Art Document

### Patent Document

Patent Document 1: Japanese Laid-Open Patent Publication No. 2021-034695

### SUMMARY

According to an aspect of the present disclosure, there is provided a method of cooling a substrate by bringing a cooler into direct contact with a stage on which the substrate is placed, and processing the substrate while rotating the stage in a state in which the cooler is moved away from the stage, the method including: cooling the cooler to a target temperature in a state in which the stage is brought into direct contact with the cooler, and cooling the stage to an initial cooling temperature; raising a temperature of the stage; controlling the temperature of the stage to a steady cooling temperature when the temperature of the stage reaches the steady cooling temperature; and placing the substrate on the stage kept at the steady cooling temperature, and continuously performing a substrate processing on a plurality of substrates while rotating the stage in a state in which the stage is moved away from the cooler.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic sectional view showing an example of a substrate processing apparatus capable of implementing a method of processing a substrate according to one embodiment.

FIGS. 2A to 2D are diagrams for explaining a substrate processing in a steady state in the substrate processing apparatus.

FIG. 3 is a diagram showing a specific example of the time required for cooling a stage, a temperature of which has risen due to the substrate processing, to an initial cooling temperature.

FIG. 4 is a diagram for explaining changes in temperature of a stage when continuous film formation is performed in a normal sequence by the substrate processing apparatus shown in FIG. 1.

FIG. 5 is a diagram showing the result of verifying a natural temperature rise of the stage caused by spacing the stage apart from the cooler in the substrate processing apparatus shown in FIG. 1.

FIG. 6 is a diagram showing an example of heating means for raising a temperature of the stage.

FIG. 7 is a flowchart showing a first processing sequence example.

FIG. 8 is a temperature chart showing the first processing sequence example.

FIG. 9 is a flowchart showing a second processing sequence example.

FIG. 10 is a temperature chart showing the second processing sequence example.

### DETAILED DESCRIPTION

Embodiments will be specifically described below with reference to the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Processing Apparatus

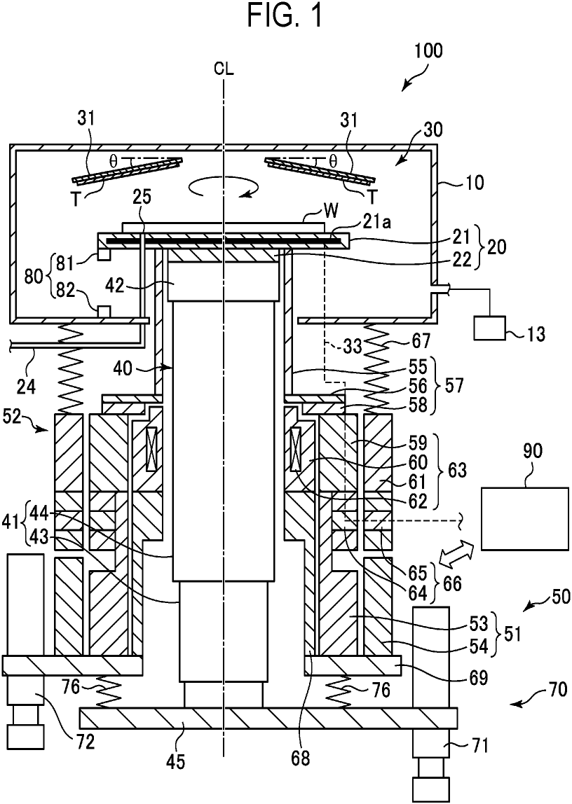

First, an example of a substrate processing apparatus capable of implementing a method of processing a substrate according to one embodiment will be described. FIG. 1 is a schematic sectional view showing an example of the substrate processing apparatus.

The substrate processing apparatus 100 shown in FIG. 1 is, for example, an apparatus for forming a desired film on a substrate W such as a semiconductor wafer or the like inside a vacuum processing container 10 that forms a vacuum atmosphere and performs substrate processing using a processing gas. The substrate processing apparatus is configured as a sputtering apparatus that performs PVD (physical vapor deposition) film formation on the substrate W.

The substrate processing apparatus 100 includes a vacuum processing container 10, a stage 20, a target part 30, a cooler 40, a rotational driver 50, an elevator 70, a temperature measurement mechanism 80, and a controller 90.

The vacuum processing container 10 is configured to perform a film-forming process on the substrate W therein. An evacuation device 13 including a vacuum pump and the like is connected to the vacuum processing container 10, and the interior of the vacuum processing container 10 is evacuated by operating the evacuation device 13. A processing gas (e.g., a noble gas such argon (Ar), krypton (Kr), neon (Ne) or the like, or a nitrogen (N₂) gas is supplied from a processing gas supply device (not shown) to the vacuum processing container 10.

The stage 20 is configured to place the substrate W thereon, and is provided in a lower portion of the vacuum processing container 10. The stage 20 has a structure in which a placement portion 21 on which the substrate W is placed, and a heat transfer part 22 provided under the placement portion 21 are stacked one above another. The placement portion 21 and the heat transfer part 22 are made of a material having high thermal conductivity, for example, copper (Cu). The placement portion 21 includes an electrostatic chuck, and the electrostatic chuck includes a chuck electrode 21a embedded in a dielectric film. A DC voltage is applied to the chuck electrode 21a through a wiring 33. Thus, the substrate W is electrostatically attracted to the electrostatic chuck. The stage 20 is provided with a temperature measuring mechanism (not shown) to monitor a temperature of the stage 20. Further, lift pins (not shown) for lifting the substrate W are provided in the stage 20 so as to move up and down with respect to an upper surface of the stage 20.

The stage 20 is provided with a heat transfer gas supply pipe 24 for supplying a heat transfer gas. The heat transfer gas supply pipe 24 extends through the placement portion 21 and supplies a heat transfer gas such as a He gas or the like between a rear surface of the substrate W and the upper surface of the placement portion 21 from the gas hole 25. This increases the thermal conductivity of the space between the rear surface of the substrate W and the upper surface of the placement portion 21, which makes it possible to improve the cooling efficiency of the substrate W.

The target part 30 is provided above the stage 20 inside the vacuum processing container 10 so as to face the stage 20. The target part 30 includes a plurality of target holders 31. The target holders 31 are fixed inside the vacuum processing container 10 while being inclined at an inclination angle θ with respect to a horizontal plane. A target T is attached to a lower surface of each of the target holders 31. The target holders 31 may be fixed horizontally.

The target part 30 includes a power source (not shown) that applies a voltage to the target holders 31. The power source may be a DC power source or a high-frequency power source. When a DC voltage or a high-frequency voltage is applied from the power source to the targets T through the target holders 31, plasma is generated inside the vacuum processing container 10, and the noble gas or the like supplied into the vacuum processing container 10 is ionized. Then, the target T is sputtered by ions of the noble gas or the like. Atoms or molecules of the sputtered target T are deposited on the surface of the substrate W held on the stage 20, so that a desired film is formed.

By inclining the target T with respect to the substrate W, the incident angle of the sputtered particles sputtered from the target T to the substrate W may be adjusted, and the in-plane film thickness uniformity of the film formed on the substrate W may be enhanced. The stage 20 may be moved up and down to change a distance between the target T and the substrate W, thereby adjusting the incident angle of the sputtered particles with respect to the substrate W.

The number of targets T is not particularly limited. From the viewpoint of sequentially forming different films made of different materials in one substrate processing apparatus 100, a plurality of targets T having different compositions may be provided.

The cooler 40 includes a refrigerating device 41 and a connection plate 42 provided on the refrigerating device 41. The refrigerating device 41 includes a refrigerator 43 and a cold link 44, and has a configuration in which the cold link 44 is stacked on the refrigerator 43. The connection plate 42 is provided so as to make contact with and move away from the heat transfer part 22 of the stage 20.

The refrigerator 43 holds the cold link 44 and may cool the upper surface of the cold link 44 to -30° C. or lower, for example, an extremely low temperature of about -200° C. The refrigerator 43 is supported by a first support member 45. From the viewpoint of cooling capacity, the refrigerator 43 may use a GM (Gifford-McMahon) cycle.

The cold link 44 is fixed on the refrigerator 43, and an upper portion thereof is accommodated in the vacuum processing container 10. The cold link 44 is made of copper (Cu) or the like having high thermal conductivity, and is formed in a substantially cylindrical shape. The refrigerator 43 and cold link 44 are arranged so that their centers coincide with the central axis CL of the stage 20.

The rotational driver 50 includes a rotation device 51 and a drive transmission part 52. The rotational driver 50 rotates the stage 20.

The rotation device 51 is composed of a direct drive motor equipped with a rotor 53 and a stator 54. The rotor 53 has a substantially cylindrical shape extending coaxially with a rotary body 64 of a slip ring 66, which will be described later, and is fixed to the rotary body 64. The stator 54 has a substantially cylindrical shape and has an inner diameter larger than the outer diameter of the rotor 53. When the rotor 53 rotates, the stage 20 rotates relative to the cold link 44 via the drive transmission part 52 as will be described later. The stator 54 is fixed to a support member 69, and the rotor 53 rotates with respect to the support member 69. The rotation device may be in a form other than the direct drive motor, and may be in a form including a servomotor and a transmission belt.

The drive transmission part 52 includes an outer cylinder 57 that supports the stage 20, a magnetic fluid seal part 63, a slip ring 66, and the like.

The outer cylinder 57 is arranged so as to cover an outer peripheral surface of the upper portion of the cold link 44, and an upper portion thereof enters the interior of the vacuum processing container 10 to support the stage 20 inside the vacuum processing container 10. The outer cylinder 57 includes a cylindrical portion 55 having an inner diameter slightly larger than the outer diameter of the cold link 44, and a flange portion 56 extending radially outward from the lower surface of the cylindrical portion 55. The cylindrical portion 55 directly supports the stage 20. The cylindrical portion 55 and the flange portion 56 are made of, for example, a metal such as stainless steel or the like.

A heat insulating member 58 is connected to a lower surface of the flange portion 56. The heat insulating member 58 has a substantially cylindrical shape extending coaxially with the flange portion 56 and is fixed to the lower surface of the flange portion 56. The heat insulating member 58 is made of ceramics such as alumina or the like.

The magnetic fluid seal part 63 is provided on a lower surface of the heat insulating member 58. The magnetic fluid seal part 63 includes a rotary portion 59, an inner fixed portion 60, an outer fixed portion 61, and a heat source 62. The rotary portion 59 has a substantially cylindrical shape extending coaxially with the heat insulating member 58 and is fixed to the lower surface of the heat insulating member 58. That is, the rotary portion 59 is connected to an outer cylinder 57 via the heat insulating member 58. With this configuration, the transfer of the cold heat of the outer cylinder 57 to the rotary portion 59 is blocked by the heat insulating member 58. This makes it possible to suppress deterioration of sealing performance and generation of dew condensation due to a decrease in the temperature of the magnetic fluid of the magnetic fluid seal part 63.

The inner fixed portion 60 is provided between the cold link 44 and the rotary portion 59 via a magnetic fluid. The inner fixed portion 60 has a substantially cylindrical shape whose inner diameter is larger than an outer diameter of the cold link 44 and whose outer diameter is smaller than an inner diameter of the rotary portion 59. The outer fixed portion 61 is provided outside the rotary portion 59 via a magnetic fluid. The outer fixed portion 61 has a substantially cylindrical shape whose inner diameter is larger than an outer diameter of the rotary portion 59. The heat source 62 is embedded in the inner fixed portion 60 to heat the entire magnetic fluid seal part 63.

In this way, the magnetic fluid seal part 63 may suppress the deterioration of sealing performance and the generation of dew condensation due to the decrease in the temperature of the magnetic fluid. With the above configuration, in the magnetic fluid seal part 63, the rotary portion 59 is rotatable with respect to the inner fixed portion 60 and the outer fixed portion 61 in an airtight state. That is, the outer cylinder 57 is rotatably supported via the magnetic fluid seal part 63.

A substantially cylindrical bellows 67 is provided between the upper surface of the outer fixed portion 61 and the lower surface of the vacuum processing container 10. The bellows 67 has a metal bellows structure that is vertically extendible. The bellows 67 surrounds the upper portion of the cold link 44, the lower portion of the outer cylinder 57, and the heat insulating member 58. The bellows 67 has a function of isolating an internal space of the vacuum processing container 10, which is maintained in a depressurized state, from an external space of the vacuum processing container 10.

A slip ring 66 is provided below the magnetic fluid seal part 63. The slip ring 66 is provided with a rotary body 64 including a metal ring, and a stationary body 65 including a brush. The rotary body 64 has a substantially cylindrical shape extending coaxially with the rotary portion 59 of the magnetic fluid seal part 63 and is fixed to the lower surface of the rotary portion 59. The stationary body 65 has a substantially cylindrical shape whose inner diameter is slightly larger than an outer diameter of the rotary body 64. The slip ring 66 is electrically connected to a DC power source (not shown) to supply the electric power supplied from the DC power source to the wiring 33 via the brush of the stationary body 65 and the metal ring of the rotary body 64. With this configuration, a potential may be applied from the DC power source to the chuck electrode without twisting the wiring 33 or the like. The slip ring 66 may have a structure other than the brush structure, such as a contactless power feeding structure, a structure having no mercury and containing a conductive liquid, or the like.

The rotary body 64 constituting the slip ring 66 supports the rotor 53 of the rotation device 51 described above. As a result, when the rotor 53 rotates, the stage 20 rotates relative to the cold link 44 via the rotary body 64, the rotary portion 59 and the outer cylinder 57 that constitute the drive transmission part 52.

A heat insulator 68 having a vacuum heat insulation dual structure is provided around the refrigerator 43 and the cold link 44. In the illustrated example, the heat insulator 68 is provided between the refrigerator 43 and the rotor 53 and between the lower portion of the cold link 44 and the rotor 53. With this configuration, it is possible to prevent cold heat of the refrigerator 43 and the cold link 44 from being transferred to the rotor 53. The heat insulator 68 is supported by a second support member 69.

The elevator 70 includes a first elevating device 71 and a second elevating device 72. The first elevating device 71 is configured to elevate the first support member 45 and elevate the cooler 40 via the first support member 45. The second elevating device 72 is configured to elevate the second support member 69 and elevate the stage 20 via the second support member 69, the rotation device 51 and the drive transmission part 52. The elevator 70 is configured to enable the heat transfer part 22 of the stage 20 and the connection plate 42 of the cooler 40 to make contact with each other and move away from each other by elevating the cooler 40 with the first elevating device 71 and elevating the stage 20 with the second elevating device 72. A substantially cylindrical bellows 76 surrounding the refrigerator 43 is provided between the upper surface of the first support member 45 and the lower surface of the second support member 69. Just like the bellows 67, the bellows 76 has a vertically extendible metal-made bellows structure.

The temperature measurement mechanism 80 includes a temperature detecting contact part 81 provided on a portion of the stage 20 that does not interfere with the placing of the substrate W, and a temperature detection part 82 attached to the bottom of the vacuum processing container 10 below the stage 20. The temperature detection part 82 includes a temperature sensor and is provided at a position spaced apart from the temperature detecting contact part 81 except when a temperature is being measured. The temperature of the stage 20 may be measured by bringing the temperature detection part 82 into contact with the temperature detecting contact part 81. The temperature detecting contact part 81 may be brought into contact with and moved away from the temperature detection part 82 by raising and lowering the stage 20. The temperature of the stage 20 is measured by matching the positions of the temperature detecting contact part 81 and the temperature detection part 82, lowering the stage 20, and bringing the temperature detecting contact part 81 into contact with the temperature detection part 82.

The controller 90 is composed of a computer, and includes a main controller composed of a CPU for controlling each component of the substrate processing apparatus, an input device, an output device, a display device, and a memory device. The main controller controls the power source of the target part 30, the processing gas supply device, the first elevating device 71 and the second elevating device 72 of the elevator 70, the refrigerator 43, and the like, and also controls the temperature of the stage 20 using the temperature measurement mechanism 80. In addition, the main controller causes the substrate processing apparatus 100 to execute a set operations based on a process recipe called from the storage medium provided in the memory device.

### Substrate Processing Method

Next, a substrate processing method performed in the substrate processing apparatus 100 will be described.

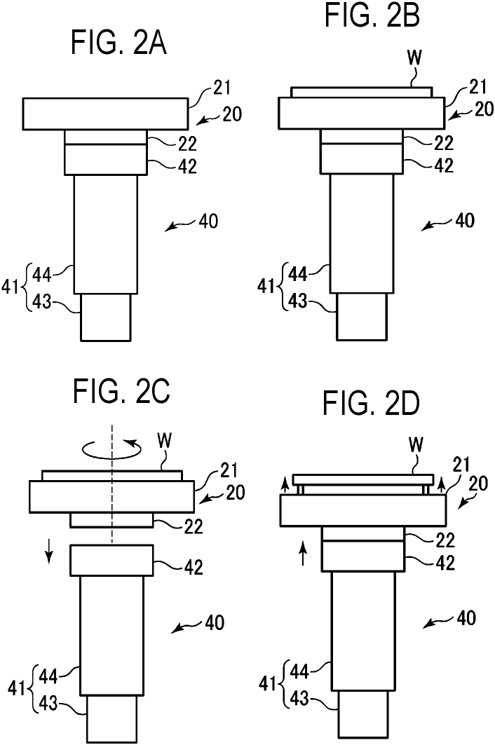

FIGS. 2A to 2D are diagrams for explaining the processing of the substrate W in a steady state in the substrate processing apparatus 100. First, while the interior of the vacuum processing container 10 is evacuated, as shown in FIG. 2A, the cooler 40 is brought into contact with the stage 20 by the elevator 70, and the refrigerator 43 of the cooler 40 is operated. As a result, the temperature of the cooler 40 is lowered, and the stage 20 is cooled by the cooler 40. Specifically, for example, by raising the cooler 40 by the first elevating device 71, the heat transfer part 22 of the cooler 40 and the connection plate 42 of the cooler 40 are brought into contact with each other. In this state, the refrigerator 43 is operated, and the stage 20 is cooled to a predetermined cooling temperature by the cold heat of the refrigerator 43.

Then, the substrate W held at a specific temperature (room temperature or higher, for example, 75° C.) is transferred from the vacuum transfer chamber into the vacuum processing container 10 by the substrate transfer device (none of which is shown), and is placed on the stage 20 as shown in FIG. 2B. At this time, a DC voltage is applied to the chuck electrode 21a to electrostatically attract the substrate W, and a heat transfer gas is supplied to the rear surface of the substrate W. As a result, the substrate W is cooled.

Next, as shown in FIG. 2C, the cooler 40 is lowered by the first elevating device 71 to move the cooler 40 away from the stage 20, and a film-forming process is performed while the stage 20 having the substrate W placed thereon is rotated by the rotation device 51 through the drive transmission part 52.

In the film-forming process, the height of the stage 20 is adjusted so that the substrate W is located at a position spaced apart by a predetermined distance from the target T, and an internal pressure of the vacuum processing container 10 is adjusted to a processing pressure. Then, while the stage 20 having the substrate W placed thereon is rotated by the rotation device 51, a voltage is applied to the target T from the power source (not shown) while introducing a processing gas into the vacuum processing container 10. Thus, plasma of the processing gas is generated, and the target T is sputtered by ions in the plasma. Atoms or molecules of the sputtered target material are deposited on the surface of the substrate W held on the stage 20, so that a desired film, for example, a magnetic film for a TMR element having a high magnetoresistance ratio may be formed. The temperature of the stage 20 at this time is monitored by the temperature measurement mechanism 80.

After the film-forming process, as shown in FIG. 2D, the stage 20 is released from the attraction, and the substrate W is unloaded by moving the substrate W away from the stage 20 using the lift pins (not shown). At this time, by bringing the stage 20 and the cooler 40 into contact with each other using the elevator 70, the stage 20 is cooled during a waiting time until the next substrate W is loaded.

A series of such processing sequences are performed on a plurality of substrates W in succession. At this time, since the stage 20 is cooled by being in contact with the cooler 40, the stage 20 may be cooled to an extremely low temperature in a short period of time with high precision, and the substrate W may be cooled to an extremely low temperature by the cooled stage 20. During the film-forming process, the stage 20 placed with the substrate W is moved away from the cooler 40 to rotate the stage 20. Therefore, the temperature of the stage 20 rises during the film-forming process.

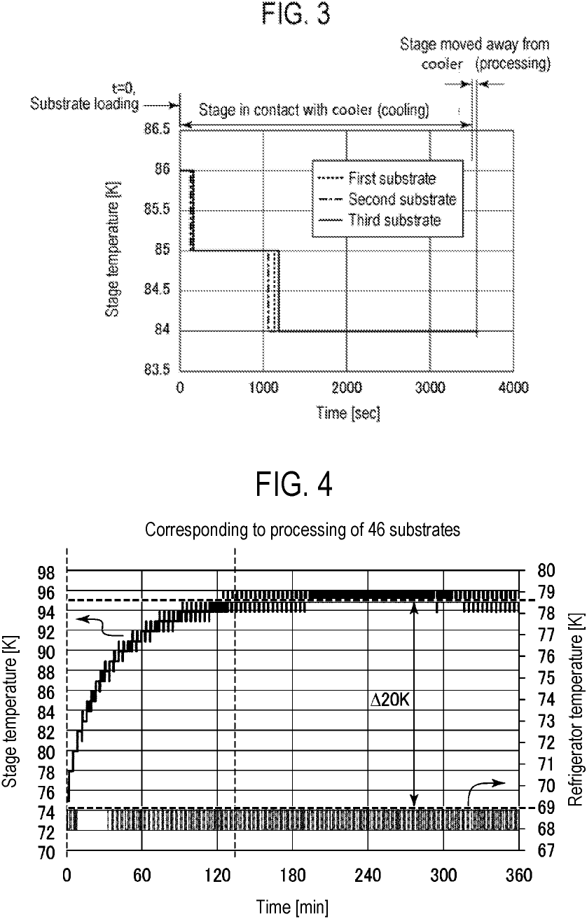

The stage 20 whose temperature has risen is cooled by bringing the stage 20 into contact with the cooler 40 before a film-forming process for the next substrate W is performed. In order to cool the temperature of the stage 20 to the initial cooling temperature. It was found that it takes a long time of several tens of minutes to cool the stage 20 to the initial cooling temperature. A specific example is shown in FIG. 3. In this regard, it may be noted that when the substrate is placed on the stage of 84 K and the temperature of the stage is raised to 86 K, it takes about 20 minutes (1,200 secs) to return the temperature of the stage to the original temperature of 84 K by bringing the cooler into contact with the stage. Therefore, when continuous film formation is performed in a normal sequence, the temperature of the stage 20 cannot be completely cooled to the initial cooling temperature during the continuous film-forming process. Heat accumulates in the stage 20, causing the temperature of the stage 20 to rise gradually. Then, after a long period of time, the temperature reaches a state of thermal equilibrium and saturates at a certain temperature. Thus, the temperature is stabilized.

For example, when the temperature of the cooler 40 (refrigerator 43) is 69 K and continuous processing is performed at a desired throughput, as shown in FIG. 4, the temperature of the stage 20 gradually rises from the initial cooling temperature of 75 K. After about 2 hours (corresponding to the processing time for 46 substrates), the temperature reaches a thermal equilibrium state of 95 K, which is about 20 K higher than the initial cooling temperature. The temperature is saturated and stabilized.

As described above, the temperatures of several tens of substrates are not stabilized until the temperature of the stage 20 after the start of processing reaches the thermal equilibrium state, resulting in uneven processing among the substrates. For this reason, several tens of substrates cannot be used as products until the temperature of the stage 20 is stabilized in the thermal equilibrium state, and a long period of preparation is required, which reduces the throughput of continuous processing for a plurality of substrates.

Therefore, in the present embodiment, the substrate W is continuously processed by controlling the temperature of the stage 20 to a steady cooling temperature in the thermal equilibrium state without performing the substrate processing until the temperature of the stage 20 is stabilized in the thermal equilibrium state.

The specific processing sequences at that time may include a first processing sequence example and a second processing sequence example described below.

### First Processing Sequence Example

First, the first processing sequence example will be described.

In the first processing sequence example, the cooler 40 is cooled to a target temperature, and the stage 20 is cooled to an initial cooling temperature. Thereafter, the temperature of the stage 20 is raised to a steady cooling temperature in a thermal equilibrium state, and a plurality of substrates W is continuously processed at that temperature.

As a method of raising the temperature of the stage 20, typically, a method may be used in which the stage 20 is moved away from the cooler 40 to allow natural temperature rise of the stage 20. Since the substrate processing apparatus 100 has a structure in which the cooler 40 and the stage 20 may be brought into contact with each other and moved away from each other, the temperature of the stage 20 may be easily raised by moving the stage 20 away from the cooler 40.

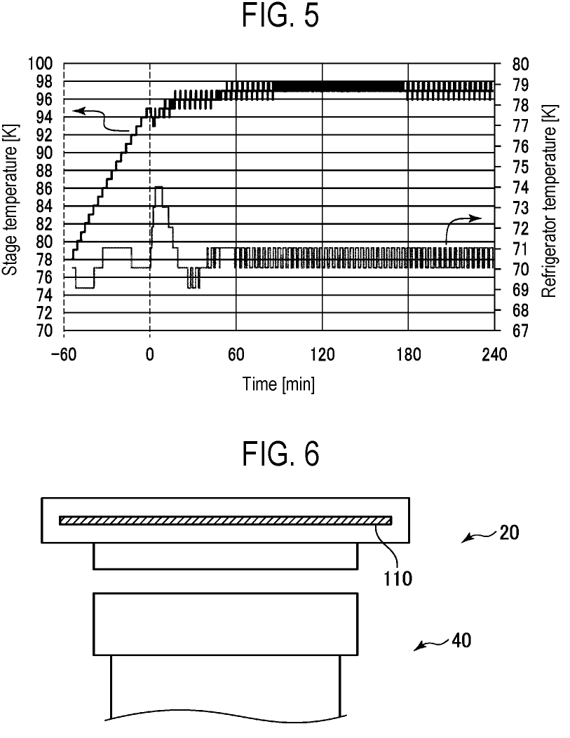

FIG. 5 is a diagram showing the result of verifying the natural temperature rise of the stage 20 by moving the stage 20 away from the cooler 40. In this example, by moving the stage 20 away from the cooler 40, the temperature of the stage 20 is increased from the initial cooling temperature (78 K) to which the stage 20 has been cooled by the cooler 40 (refrigerator 43), to 95 to 98 K corresponding to a steady cooling temperature in a thermal equilibrium state. As shown in FIG. 5, by moving the stage 20 away from the cooler 40, the temperature of the stage 20 is increased from the initial cooling temperature to the steady cooling temperature in the thermal equilibrium state in about 60 minutes. From this, it may be seen that by moving the stage 20 away from the cooler 40, the temperature of the stage 20 may be efficiently brought to the temperature in the thermal equilibrium state.

Another method of raising the temperature of the stage 20, a method may be used in which the stage 20 is forcibly heated by a heating means such as a heater or the like. For example, as shown in FIG. 6, the temperature of the stage 20 may be raised by installing a heater 110 on the stage 20 and heating the stage 20 with the heater 110.

When the method of heating the stage 20 by the heating means is adopted, from the viewpoint of not affecting the cooler 40, as shown in FIG. 6, it is preferable to heat the stage 20 in a state in which the stage 20 is moved away from the cooler 40. By heating the stage 20 with the heating means while the stage 20 is moved away from the cooler 40, both the temperature raising effect obtained by moving the stage 20 away from the cooler 40 and the temperature raising effect obtained by the heating means may be obtained. As a result, the temperature of the stage may be brought to the temperature in the thermal equilibrium state in a shorter period of time.

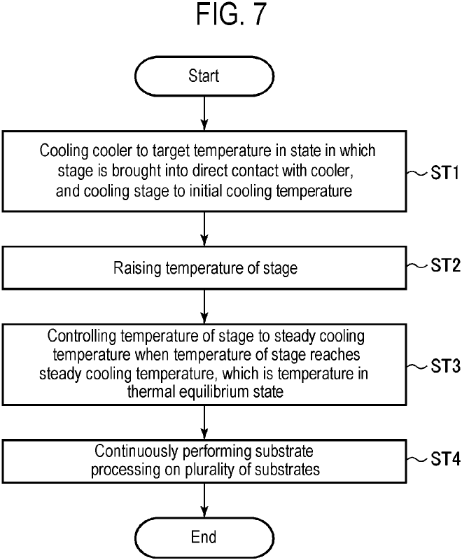

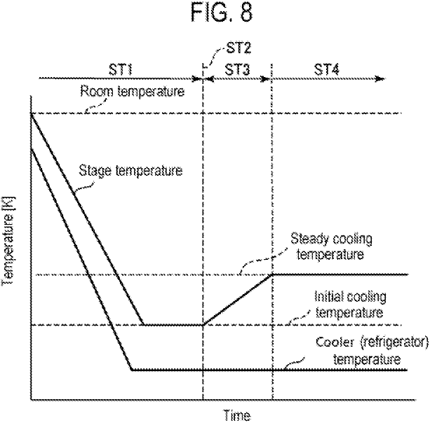

The first processing sequence example will be described more specifically with reference to FIGS. 7 and 8. FIG. 7 is a flowchart showing the first processing sequence example, and FIG. 8 is a temperature chart showing the first processing sequence example.

First, the cooler 40 is cooled to a target temperature by operating the refrigerator 43 in a state in which the stage 20 is brought into contact with the cooler 40, and the stage 20 is cooled to an initial cooling temperature (step ST1). In step ST1, the refrigerator 43 is operated to start cooling the cooler 40 kept at the room temperature, cool the cooler 40 to the target temperature (e.g., 70 K), and stabilize the stage 20 at the initial cooling temperature (e.g., 75 K) by heat transfer.

Subsequently, the temperature of the stage 20 is raised (step ST2). In step ST2, as described above, the temperature of the stage 20 may be raised by using the natural temperature rise of the stage 20 achieved by moving the stage 20 away from the cooler 40, or by forcibly heating the stage 20 with the heating means such as a heater or the like. Moving the stage 20 away from the cooler 40 and forcibly heating the stage 20 by the heating means may be used in combination. As a result, the temperature of the stage 20 may be raised to the steady cooling temperature in a shorter period of time than when the temperature of the stage 20 is naturally raised by merely moving the stage 20 away from the cooler 40.

Subsequently, when the temperature of the stage 20 reaches a steady cooling temperature, which is a temperature in a thermal equilibrium state, the temperature of the stage 20 is controlled to the steady cooling temperature (step ST3). The temperature control at this time is performed by the controller 90 based on the temperature monitored by the temperature measurement mechanism 80. The temperature control at this time may be performed with an accuracy of ±1 K, for example. The controller 90 controls the temperature of the stage 20 by bringing the stage 20 and the cooler 40 into contact with each other or moving the stage 20 and the cooler 40 away from each other based on the temperature detected by the temperature measurement mechanism. For example, when the temperature measurement mechanism detects that the temperature of the stage 20 is 1 K higher than the target temperature, the cooler 40 is moved upward to contact with the stage 20 and cool the stage 20. On the other hand, when it is detected that the temperature of the stage 20 is 1 K lower than the target temperature, the cooler 40 is moved away from the stage 20 to raise the temperature of the stage 20. The temperature of the stage 20 may be raised by the heating means (e.g., the heater 110), or may be raised by moving the stage 20 away from the cooler 40 and heating the stage 20 by the heating means. Such control is repeated to stabilize the temperature of the stage 20 at the steady cooling temperature. The accuracy of the temperature control at this time is appropriately set according to requirements.

After the temperature of the stage 20 is stabilized at the steady cooling temperature in step ST3, film formation processing is continuously performed on a plurality of substrates W according to the procedure shown in FIGS. 2A to 2D (step ST4).

The processing sequence of steps ST1 to ST4 is executed according to a process recipe pre-stored in the controller 90.

According to the first process sequence example, after the stage 20 is cooled to the initial cooling temperature by the cooler 40, the stage 20 is moved away from the cooler 40, or the temperature of the stage 20 is raised to the steady cooling temperature by the heating means. Therefore, it is not necessary to process the substrates until the temperature of the stage 20 reaches the steady cooling temperature, which makes it possible to suppress non-uniformity in processing between substrates. Moreover, the time required for the stage 20 to reach the steady cooling temperature is short, and high throughput processing is possible.

### Second Processing Sequence Example

Next, the second processing sequence example will be described.

In the second processing sequence example, the refrigerator 43 is operated to cool the cooler 40. In this process, when the temperature of the stage 20 reaches the temperature in the thermal equilibrium state, the temperature of the stage 20 is controlled to become that temperature. When the cooler 40 is cooled to a target temperature, a plurality of substrates W is continuously processed.

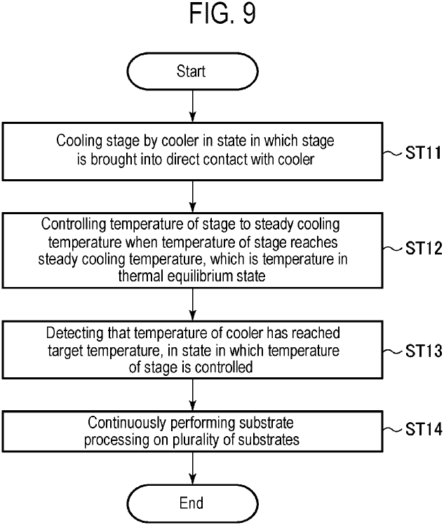

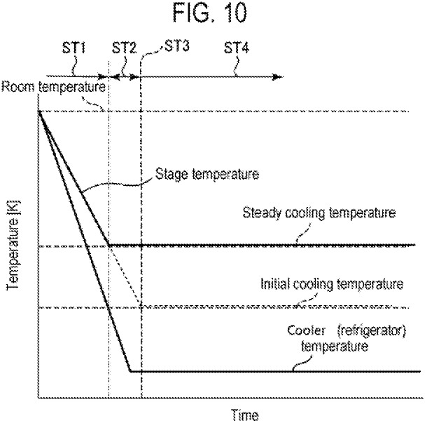

The second processing sequence example will be described more specifically with reference to FIGS. 9 and 10. FIG. 9 is a flowchart showing the second processing sequence example, and FIG. 10 is a temperature chart showing the second processing sequence example.

First, while the stage 20 is brought into contact with the cooler 40, the refrigerator 43 is operated to cool the cooler 40, thereby cooling the stage 20 (step ST11).

Next, when the temperature of the stage 20 reaches the steady cooling temperature, which is the temperature in the thermal equilibrium state, the temperature of the stage 20 is controlled to become the steady cooling temperature in the thermal equilibrium state (step ST12). The temperature control at this time is performed by the controller 90 based on the temperature monitored by the temperature measurement mechanism 80. The temperature control at this time may be performed with an accuracy of ±1 K, for example. For example, when the temperature measurement mechanism detects that the temperature of the stage 20 is 1 K higher than the target temperature, the controller 90 causes the cooler 40 to move upward so as to contact with the stage 20 and cool the stage 20. On the other hand, when it is detected that the temperature of the stage 20 is 1 K lower than the target temperature, the cooler 40 is moved away from the stage 20 to raise the temperature of the stage 20. The temperature of the stage 20 may be raised by the heating means, or may be raised by moving the stage 20 away from the cooler 40 and heating the stage 20 by the heating means. Such control is repeated to stabilize the temperature of the stage 20 at the steady cooling temperature. The accuracy of the temperature control at this time is appropriately set according to requirements.

Subsequently, after the temperature of the stage 20 is controlled in step ST12, it is detected that the temperature of the cooler 40 (refrigerator 43) has reached a target temperature (step ST13).

When it is detected that the cooler 40 (refrigerator 43) has reached the target temperature, film formation processing is continuously performed on a plurality of substrates W based on the procedure shown in FIGS. 2A to 2D (step ST14).

The processing sequence of steps ST11 to ST14 is executed according to a process recipe pre-stored in the controller 90.

According to the second process sequence example, while cooling the stage 20 by the cooler 40, the temperature of the stage 20 is controlled to become the steady cooling temperature. Therefore, it is not necessary to process the substrates until the temperature of the stage 20 reaches the steady cooling temperature, which makes it possible to suppress non-uniformity in processing between substrates. Moreover, since it does not take time to raise the temperature of the stage 20 to the steady cooling temperature, processing may be performed with a higher throughput than in the first processing sequence example.

### Other Applications

Although the embodiment has been described above, the embodiment disclosed herein should be considered to be exemplary and not limitative in all respects. The above-described embodiment may be omitted, substituted, or modified in various ways without departing from the scope and spirit of the appended claims.

For example, in the above-described embodiment, the sputtering deposition of the magnetic film used for the TMR element has been described as an example of the substrate processing. However, the present disclosure is not limited to the above-described embodiment as long as the cooler is brought into contact with the stage holding the substrate to directly cool the stage, and the substrate is processed while rotating the stage in a state in which the cooler is moved away from the stage.

Further, in the above-described embodiment, the example in which the semiconductor wafer is used as the substrate has been described. However, the substrate is not limited to the semiconductor wafer, and may be other substrates such as an FPD (flat panel display) substrate or a ceramic substrate.

According to the present disclosure in some embodiments, it is possible to provide a method and apparatus capable of processing a substrate with high throughput while suppressing non-uniformity in processing between substrates when the substrate is cooled by bringing a cooler into direct contact with a stage that supports the substrate and is processed while rotating the stage in a state in which the cooler is moved away from the stage.

What is claimed is:

1. A method of cooling a substrate by bringing a cooler into direct contact with a stage on which the substrate is placed, and processing the substrate while rotating the stage in a state in which the cooler is moved away from the stage, the method comprising:
cooling the cooler to a target temperature in a state in which the stage is brought into direct contact with the cooler, and cooling the stage to an initial cooling temperature;
raising a temperature of the stage;
controlling the temperature of the stage to a steady cooling temperature when the temperature of the stage reaches the steady cooling temperature; and
placing the substrate on the stage kept at the steady cooling temperature, and continuously performing a substrate processing on a plurality of substrates while rotating the stage in a state in which the stage is moved away from the cooler.

2. The method of claim 1, wherein the raising the temperature of the stage is performed by moving the cooler away from the stage.

3. The method of claim 1, wherein the raising the temperature of the stage is performed by heating the stage with a heater.

4. The method of claim 1, wherein the raising the temperature of the stage is performed by heating the stage with a heater while moving the cooler away from the stage.

5. A method of cooling a substrate by bringing a cooler into direct contact with a stage on which the substrate is placed, and processing the substrate while rotating the stage in a state in which the cooler is moved away from the stage, the method comprising:
cooling the stage by the cooler in a state in which the stage is brought into direct contact with the cooler;
controlling a temperature of the stage to a steady cooling temperature when the temperature of the stage reaches the steady cooling temperature;
detecting that a temperature of the cooler has reached a target temperature, in a state in which the temperature of the stage is controlled; and
placing the substrate on the stage kept at the steady cooling temperature, and continuously performing a substrate processing on a plurality of substrates while rotating the stage in a state in which the stage is moved away from the cooler.

6. The method of claim 5, wherein the controlling the temperature of the stage to the steady cooling temperature is performed by bringing the stage and the cooler into contact with each other and moving the stage and the cooler away from each other based on the temperature of the stage detected by a temperature measurement mechanism.

7. The method of claim 6, wherein the cooler includes a refrigerator provided below the stage, and a cold link configured to transfer cold heat from the refrigerator to the stage.

8. The method of claim 7, wherein the substrate processing is a sputtering film formation in which the stage is arranged inside a vacuum container and particles sputtered from a target arranged above the stage inside the vacuum container are deposited on the substrate in a vacuum state.

9. The method of claim 1, wherein the controlling the temperature of the stage to the steady cooling temperature is performed by bringing the stage and the cooler into contact with each other and moving the stage and the cooler away from each other based on the temperature of the stage detected by a temperature measurement mechanism.

10. The method of claim 1, wherein the cooler includes a refrigerator provided below the stage, and a cold link configured to transfer cold heat from the refrigerator to the stage.

11. The method of claim 1, wherein the substrate processing is a sputtering film formation in which the stage is arranged inside a vacuum container and particles sputtered from a target arranged above the stage inside the vacuum container are deposited on the substrate in a vacuum state.

12. An apparatus for processing a substrate, comprising:
a stage provided rotatably and configured to place the substrate on the stage;
a cooler provided to be come into contact with and move away from the stage;
a mechanism configured to bring the stage and the cooler into contact with each other and move the stage and the cooler away from each other;
a rotation mechanism configured to rotate the stage;
a means configured to raise a temperature of the stage;
a processing mechanism configured to process the substrate; and
a controller,
wherein the controller is configured to execute a control so as to perform:
cooling the cooler to a target temperature in a state in which the stage is brought into direct contact with the cooler, and cooling the stage to an initial cooling temperature;
raising the temperature of the stage;
controlling the temperature of the stage to a steady cooling temperature when the temperature of the stage reaches the steady cooling temperature; and
placing the substrate on the stage kept at the steady cooling temperature, and continuously performing a substrate processing on a plurality of substrates while rotating the stage in a state in which the stage is moved away from the cooler.

13. The apparatus of claim 12, wherein the means configured to raise the temperature of the stage includes an elevating device configured to bring the cooler and the stage into contact with each other and move the cooler and the stage away from each other, and the temperature of the stage is raised by moving the cooler and the stage away from each other.

14. The apparatus of claim 12, wherein the means configured to raise the temperature of the stage includes a heating means configured to heat the stage.

15. The apparatus of claim 12, wherein the means configured to raise the temperature of the stage includes an elevating device configured to bring the cooler and the stage into contact with each other and move the cooler and the stage away from each other, and a heating means configured to heat the stage, and
wherein the raising the temperature of the stage is performed by heating the stage with the heating means while moving the cooler away from the stage.

16. The apparatus of claim 12, wherein the controller is configured to control the temperature of the stage to the steady cooling temperature by bringing the stage and the cooler into contact with each other and moving the stage and the cooler away from each other based on the temperature of the stage detected by a temperature measurement mechanism.

17. An apparatus for processing a substrate, comprising:
a stage provided rotatably and configured to place the substrate on the stage;
a cooler provided to be come into contact with and move away from the stage;
a mechanism configured to bring the stage and the cooler into contact with each other and move the stage and the cooler away from each other;
a rotation mechanism configured to rotate the stage;
a processing mechanism configured to process the substrate; and
a controller configured to control a temperature of the stage,
wherein the controller is configured to execute a control so as to perform:
cooling the stage by the cooler in a state in which the stage is brought into direct contact with the cooler;
controlling the temperature of the stage to a steady cooling temperature when the temperature of the stage reaches the steady cooling temperature;
detecting that the temperature of the cooler has reached a target temperature, in a state in which the temperature of the stage is controlled; and
placing the substrate on the stage kept at the steady cooling temperature, and continuously performing a substrate processing on a plurality of substrates while rotating the stage in a state in which the stage is moved away from the cooler.

18. The apparatus of claim 17, wherein the controller is configured to control the temperature of the stage to the steady cooling temperature by bringing the stage and the cooler into contact with each other and moving the stage and the cooler away from each other based on the temperature of the stage detected by a temperature measurement mechanism.

19. The apparatus of claim 18, wherein the cooler includes a refrigerator provided below the stage, and a cold link configured to transfer cold heat from the refrigerator to the stage.

20. The apparatus of claim 19, wherein the stage is arranged inside a vacuum container, and
wherein the processing mechanism includes a sputtering part provided with a target arranged above the stage inside the vacuum container and a power source configured to apply a voltage to the target, and is configured to perform a sputtering film formation in which particles sputtered from the target are deposited on the substrate.
